(19) United States
(12) Patent Application Publication
(10) Pub. No.: US 2010/0113118 A1
(43) Pub. Date: May 6, 2010

(54) RFID-INCORPORATED GAME CARD AND MANUFACTURING METHOD THEREOF

(75) Inventor: Yasushi Shigeta, Osaka (JP)

Correspondence Address: LOWE HAUPTMAN HAM & BERNER, LLP, 1700 DIAGONAL ROAD, SUITE 300, ALEXANDRIA, VA, 22314, US

(73) Assignee: ANGEL PLAYING CARDS CO., LTD., Osaka (JP)

(21) Appl. No.: 12/593,657

(22) PCT Filed: Mar. 28, 2008
(86) PCT No.: PCT/JP2008/056185

§ 371 Date: Jan. 10, 2010

(30) Foreign Application Priority Data
Mar. 30, 2007 (JP) 2007-093930

(51) Int. Cl. A63F 9/24; H05K 13/00

(52) U.S. Cl. 463/11; 29/592.1

(57) ABSTRACT

An RFID tag-incorporated game card having no irregularities on its surface layers is provided. In a card, an intermediate layer having an RFID tag incorporated therein with an appropriately uniform thickness is held between at least two sheets. The intermediate layer includes the RFID tag and at least two base films arranged to hold the RFID tag between them. The base films are preferably colored black. Alternatively, it is also preferable that the intermediate layer and the sheets are adhered to each other using a black adhesive.

### TECHNICAL FIELD

The present invention relates to game cards such as playing cards and hanafuda (Japanese playing cards) and particularly to RFID-incorporated game cards.

### BACKGROUND ART

In recent years, as the development of RFID tags has been advanced, the use of RFID-incorporated game cards and systems using such cards have been proposed for the purpose of alleviating point calculation process or preventing fraudulent conduct. For example, JP 2005-342175 A discloses (e.g., in paragraph [0018]) game cards each including two thin plastic plates with an IC tag and an antenna held therebetween.

### DISCLOSURE OF THE INVENTION

### Problems to be Solved by the Invention

Ordinary playing cards without RFID tags are produced by laminating two sheets such as plastic sheets and paper sheets and the cards generally have a thickness of about 0.3 mm. However, IC chips and antennas for RFID tags distributed today are each about as thick as 0.03 mm. Therefore, if an IC tag and an antenna are held between two such plastic sheets as in the disclosure of JP 2005-342175 A, the surface layers of the playing card may have irregularities.

In order to guarantee fairness in games, game cards such as playing cards, especially those used in a place like casino, must totally lack individuality so that the cards cannot be distinguished from one another when viewed from the back. If there are irregularities on the surface layer of a card, such a demand cannot be met.

In view of the above-described problem, it is therefore an object of the present invention to provide an RFID tag-incorporated game card having no irregularities on the surface layers.

### Means for Solving the Problems

In order to achieve the above-described object, a game card according to the present invention has an RFID tag held between at least two sheets, and the RFID tag is held between the above-described at least two sheets while the RFID tag is incorporated in an intermediate layer having an approximately uniform thickness (a first aspect). According to the first aspect, the incorporation of the RFID tag in the intermediate layer having an approximately uniform thickness allows a game card without irregularities on the surface layers to be obtained when the RFID tag is incorporated.

In the game card according to the first aspect, the intermediate layer preferably includes the RFID tag and at least two base films arranged to hold the RFID tag therebetween (a second aspect). Alternatively, the intermediate layer preferably includes a base film having the RFID tag embedded therein so that the surface of the tag does not protrude (a third aspect). In any of the aspects, a game card without irregularities on the surface layers can be provided even when an RFID tag is incorporated.

According to the second or third aspect, the base film is preferably colored black (a fourth aspect). Alternatively, in the first to third aspects, the sheets and the intermediate layer are preferably adhered to each other using a black adhesive (a fifth aspect). Otherwise, in the second aspect, at least two base films are preferably adhered to each other using a black adhesive (a sixth aspect). According to the fourth and fifth aspects, marks, numbers or the like on the front surface can be prevented from being recognized through the back surface.

In the game card according to the first aspect, the intermediate layer is preferably an adhesive layer that adheres the above-described at least two sheets (a seventh aspect). According to this aspect, the intermediate layer also serves as an adhesive layer, the thickness of the game card is not increased when the RFID tag is incorporated. In addition, in the seventh aspect, the adhesive layer is preferably colored black (an eighth aspect). In this way, marks, numbers or the like on the front surface can be prevented from being recognized through the back surface.

Furthermore, in order to achieve the above-described object, a game card according to the present invention includes at least two sheets and an RFID tag held between the sheets, at least one of the-above described at least two sheets has a degree of plasticity that absorbs the thickness of the RFID tag (a ninth aspect). According to the ninth aspect, the RFID tag is held between at least two sheet including a sheet having a degree of plasticity that absorbs the thickness of the tag, and therefore a game card without irregularities on the surface layers can be provided even when the RFID tag is incorporated. In the ninth aspect, a sheet including foams for example may be used as the sheet having plasticity (a tenth aspect).

In the ninth or tenth aspect, the sheets are preferably adhered to each other using a black adhesive with the RFID tag interposed therebetween (an eleventh aspect). In this way, marks, numbers or the like on the front surface can be prevented from being recognized from the back surface side.

In order to achieve the above-described object, a first method of manufacturing a game card according to the present invention is a method of manufacturing a game card having an RFID tag-incorporated intermediate layer held between at least two sheets, the intermediate layer has an approximately uniform thickness, and the method includes the steps of having a plurality of RFID tags incorporated in the intermediate layer, forming a layered body having the intermediate layer held between at least two sheets, and cutting individual game cards from the layered body. According to the manufacturing method, a game card without irregularities on the surface layers can efficiently be produced even when an RFID tag is incorporated.

In order to achieve the above-described object, a second method of manufacturing a game card according to the present invention is a method of manufacturing a game card having an RFID tag held between at least two sheets including a sheet having a degree of plasticity that absorbs the thickness of the RFID tag, and the method includes the steps of providing a plurality of RFID tags on at least one of the two sheets, forming a layered boy produced by providing at least one sheet on the sheet having the plurality of RFID tags provided thereon, and cutting individual game cards out from the layered body. Also according to the manufacturing method, a game card without irregularities on the surface layers can efficiently be produced even when an RFID tag is incorporated.

The first or second manufacturing method preferably includes the step of printing a mark and/or a number on the surfaces of the sheets before the step of forming the layered body. Furthermore, the step of recording the plurality of RFID tags with pieces of information different from one another that correspond to the mark and/or the number printed on the sheets is preferably included.

### Effects of the Invention

According to the present invention, an RFID tag-incorporated game card without irregularities on the surface layers can be provided.

### BRIEF DESCRIPTION OF THE DRAWINGS

FIG. 1A is a plan view of a playing card according to a first embodiment of the present invention.

FIG. 1B is a sectional view taken along A-A′ in FIG. 1A.

FIG. 2 is a process view schematically showing essential steps in the process of manufacturing playing cards according to the first embodiment.

FIG. 3 is a sectional view of a modification of the playing card according to the first embodiment.

FIG. 4 is a sectional view of the structure of a playing card according to a second embodiment.

FIG. 5 is a sectional view of the structure of a playing card according to a third embodiment.

### BEST MODE FOR CARRYING OUT THE INVENTION

Now, embodiments of the present invention will be described in detail with reference to the accompanying drawings.

### First Embodiment

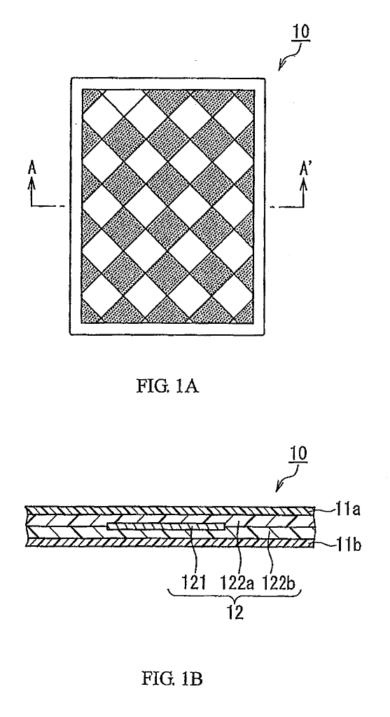

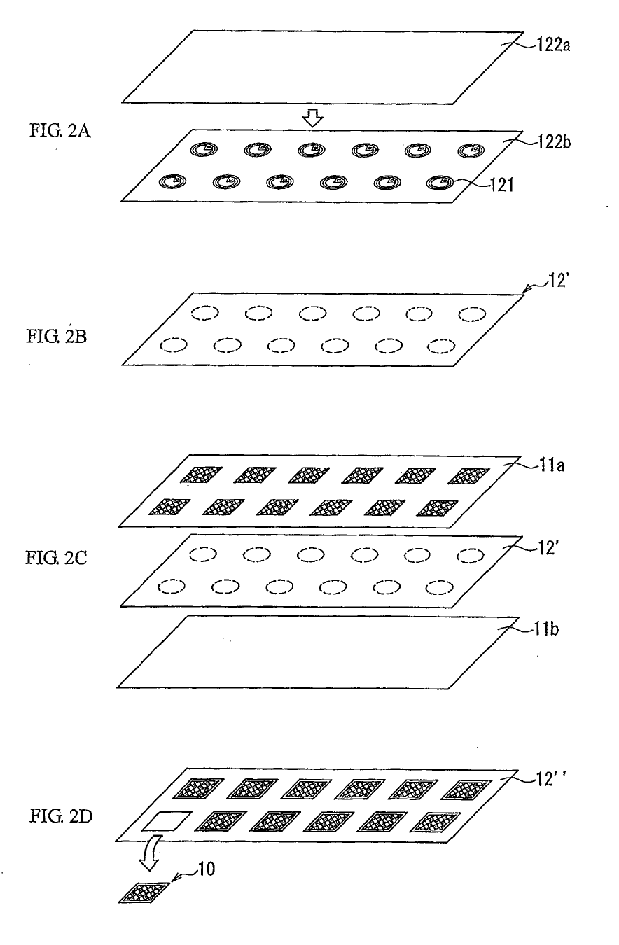

FIG. 1 includes views showing the structure of a playing card 10 as a game card according to a first embodiment of the present invention, FIG. 1A is a plan view of the playing card 10 and FIG. 1B is a sectional view of the playing card 10 taken along A-A′ in FIG. 1A. Note that in FIGS. 1A, 1B and 2 and the other figures, elements of each playing card are not drawn in actual size.

The playing card 10 according to the present embodiment has marks and numbers printed on one surface (the front surface that is not shown) and an arbitrary pattern or design such as a geometrical pattern printed on the back surface as shown in FIG. 1A and looks exactly like a conventional playing card in appearance. The playing card 10 however includes an intermediate layer 12 including an RFID tag 121 between two surface layer sheets 11a and 11b that form the front and back surfaces of the playing card as shown in FIG. 1B. The intermediate layer 12 has a substantially uniform thickness across the entire surface. The surface layer sheets 11a and 11b each have a thickness of about 75 μm, and the intermediate layer 12 has a thickness of about 150 μm. Paper or a resin film such as vinyl chloride and PET (polyethylene terephthalate) is used for the surface layer sheets 11a and 11b.

In the intermediate layer 12, the RFID tag 121 is held between two base films 122a and 122b having plasticity. The RFID tag 121 includes an IC chip and an antenna for radio communication (both not shown). The IC chip of the RFID tag 121 can be recorded with various kinds of information. Examples of such information include information indicating the marks and/or numbers printed on the front surface of the playing card 10, information indicating the manufacturer of the playing card 10, information indicating the owner of the playing card 10, information indicating the date of manufacture of the playing card 10, information indicating the date on which the playing card 10 was obtained by the owner, information indicating the period in which the playing card 10 can effectively be used and information indicating the place where the playing card 10 can effectively be used. Needless to say, information that can be recorded on the IC chip of the RFID tag 121 is not limited to the above-described examples. Note that the marks and/numbers are printed on the surface layer sheets 11a and 11b, and these marks and/or numbers are printed before the RFID tag 121 is held between the two surface layer sheets 11a and 11b that form the front and back surfaces of the card, so that printing misregistration or the like may be minimized. A plurality of RFID tags 121 include different kinds of information among one another, and marks and/or numbers printed on the surface layer sheets 11a and 11b correspond to the tags, so that manufactured cards can more surely prevent misconduct.

Examples of the material of the base films 122a and 122b preferably include paper, vinyl chloride and polyethylene terephthalate, while the material is not limited to the above. More specifically, the base films 122a and 122b need only have a degree of plasticity that allows the films to conform to the contour of the RFID tag 121 held between them with the smallest possible gap and the thickness of the RFID tag 121 to be absorbed so that the thickness of the layered body (intermediate layer 12) is substantially uniform across the entire surface and the surface layers of the playing card 10 have no irregularities. In addition, when a thermal press-bonding step is included in the process of manufacturing the playing card 10, the base films 122a and 122b also serve to protect the RFID tag 121 against heat and pressure during the thermal press-bonding step.

Note that the base films 122a and 122b are preferably colored black in order to prevent light from being transmitted therethrough. Alternatively, a black adhesive that absorbs light is preferably used to laminate the base films 122a and 122b to each other. Furthermore, a black adhesive is preferably used to laminate the intermediate layer 12 and the surface layer sheets 11a and 11b to each other. According to the preferred arrangements, the following effects are provided.

More specifically, the playing card 10 according to the present embodiment has the intermediate layer 12 inserted therein and therefore the surface layer sheets 11a and 11b must be thinner than those in the conventional example in order to make the total thickness of the playing card 10 about equal to that of the conventional playing card (normally about 300 μm). In other words, in the conventional playing card produced by laminating two surface layer sheets, the thickness of one surface layer sheet is about 150 μm, while in the playing card according to the present embodiment, the surface layer sheets 11a and 11b each have a thickness of 75 μm, which is about half the thickness of the conventional sheet as described above. When the surface layer sheets 11a and 11b are reduced in thickness in this way, the numbers and signs on the front surface may be seen through the back surface in some cases. Therefore, the use of the black base film or adhesive as described above can prevent the front surface from being seen through even when the surface layer sheets 11a and 11b are reduced in thickness.

Now, with reference to FIG. 2, an example of a method of manufacturing the playing card 10 will be described. In this example, an adhesive (not shown) is applied on a base film 122b, and a plurality of RFID tags 121 are arranged at prescribed intervals as shown in FIG. 2A. Then, another base film 122a is placed thereon, and then the two films 122a and 122b are laminated to each other by the adhesive. In this way, as shown in FIG. 2B, a layered body 12′ having the plurality of RFID tags 121 held between the two base films 122a and 122b is formed. Note that FIGS. 2A and 2B show an example only and the number of RFID tags 121 arranged on the base film 122b is arbitrary.

Now, patterns or designs for the front and back surfaces are printed on the surface layer sheets 11a and 11b. Then, as shown in FIG. 2C, the layered body 12′ is held between the surface layer sheets 11a and 11b after printing, and a layered body 12″ as shown in FIG. 2D is formed by adhesion with an adhesive or fusion press bonding by heating. In this way, printing to the surface layer sheets 11a and 11b is carried out before the layers are laminated to the layered body 12′ having the RFID tags 121 incorporated therein, so that the RFID tags 121 can be prevented from being destroyed by pressure otherwise applied by the rollers or the like of a printer. In consideration of the possibility that the RFID tags 121 still cause printing misregistration even if they are held between the base films 122a and 122b during the pressing process between the rollers of the printer, printing to the surface layer sheets 11a and 11b is preferably carried out before they are laminated to the layered body 12′ having the RFID tags 121 incorporated therein.

Then, as shown in FIG. 2D, playing cards 10 are cut out from the layered body 12″ by punching processing as shown in FIG. 2D. Through the above-described process, the playing cards 10 can be manufactured efficiently. Note that before or after the step in FIG. 2C, the printing surfaces of the surface layer sheets 11a and 11b may be subjected to over-coating. Note however that over-coating treatment carried out at high temperatures is preferably performed before the step in FIG. 2C in order to prevent the RFID tags 121 from being destroyed by the heat.

Note that the RFID tags 121 provided on the base film 122b in FIG. 2A are each produced by forming an IC chip and an antenna on a base material such as a resin sheet having a relatively small area. However, if for example a product including a plurality of RFID tags 121 formed on a single base material is commercially available from an RFID tag manufacturer, the base material may be used as the base film 122b and the other base film 122a may be provided thereon, so that the layered body 12′ may be formed.

As in the foregoing, in the playing card 10 according to the present embodiment, the intermediate layer 12 having the RFID tag 121 incorporated therein is formed to have a substantially uniform thickness. Therefore, the RFID tag 121 may be incorporated without irregularities on the surface layers of the card 10.

Note that according to the present embodiment, the RFID tag 121 is held between the two surface layer sheets 11a and 11b by way of illustration, while three or more surface layer sheets may be used. In FIG. 1B, the two base films 122a and 122b are used to hold the RFID tag 121 as an example, while three or more base films may be used.

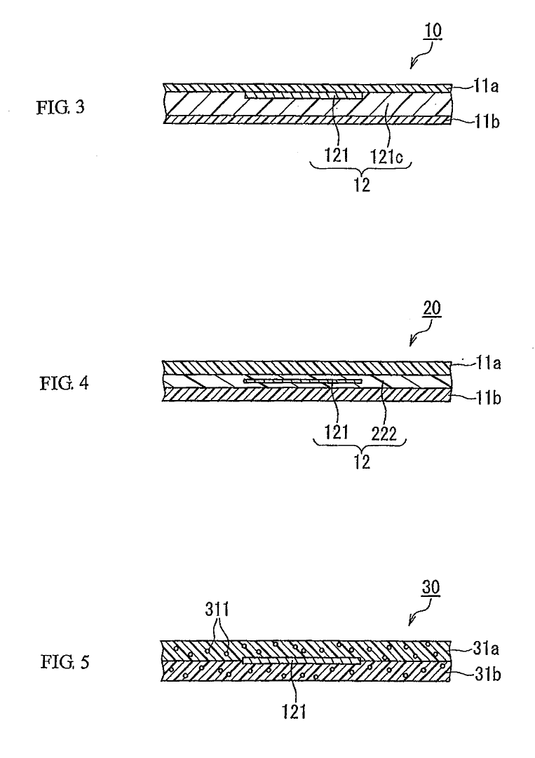

As shown in FIG. 3, the RFID tag 121 may be embedded so that its surface is flush with the surface of a base film 122c and the obtained structure may be used as the intermediate layer 12. Also in this example, the base film 122c is preferably colored black or the intermediate layer 12 and the surface layer sheets 11a and 11b are preferably adhered to each other using a black adhesive.

### Second Embodiment

FIG. 4 is a sectional view of the structure of a playing card 20 as a game card according to a second embodiment of the present invention.

As shown in FIG. 4, in the playing card 20 according to the present embodiment, an intermediate layer 22 including an RFID tag 121 is held between surface layer sheets 11a and 11b. The intermediate layer 22 includes the RFID tag 121 and an adhesive layer 222 having the RFID tag 121 embedded so that the tag does not protrude beyond the surface.

The adhesive layer 222 is made of an adhesive that is colored black and has a substantially uniform thickness. The thickness is for example about 40 μm. The surface layer sheets 11a and 11b each have a thickness of about 130 μm. Therefore, the total thickness of the playing card 20 is about 300 μm.

The playing card 20 can be produced in the following manner. An adhesive is applied on the surface layer sheet 11b to form an adhesive layer 222, an RFID tag 121 is embedded therein and the surface sheet 11a is placed thereon, followed by appropriate pressurizing, so that the adhesive layer 222 is solidified. Note that for the same reason as that described in connection with the first embodiment, printing is preferably carried out in advance to the surface layer sheets 11a and 11b. Alternatively, an adhesive layer 222 may be provided at each of the surface layer sheets 11a and 11b, an RFID tag 121 may be held between the adhesive layers 222, and then the adhesive layers 222 may be solidified.

Note that similarly to the manufacturing process described in connection with the first embodiment, a plurality of RFID tags 121 may be embedded in the surface layer sheet 11b provided with an adhesive, the surface layer sheet 11a may be laminated thereon, and then cards 20 may be cut out by punching processing, so that the production efficiency can be improved.

As in the foregoing, in the playing card 20 according to the present embodiment, the intermediate layer 22 including the RFID tag 121 is formed to have a substantially uniform thickness. Therefore, the RFID tag 121 can be incorporated without irregularities on the surface layers of the playing card 20.

In the playing card 20, the intermediate layer 21 includes the adhesive layer 222 that serves as an adhesive layer, so that the card can be prevented from being increased in thickness by the incorporation of the RFID tag 121.

Note that according to the present embodiment, the RFID tag 121 is held between the two surface layer sheets 11a and 11b by way of illustration, while three or more surface layer sheets may be used.

### Third Embodiment

FIG. 5 is a sectional view of the structure of a playing card 30 as a game card according to a third embodiment of the invention.

As shown in FIG. 5, in the playing card 30 according to the present embodiment, RFID tag 121 is held between surface layer sheets 31a and 31b with plasticity. The surface layer sheets 31a and 31b need only have a degree of plasticity that allows the sheets to conform to the contour of the RFID tag 121 held between them with the smallest possible gap and the thickness of the RFID tag 121 to be absorbed so that the thickness is substantially uniform across the entire surface and the surface layers of the playing card 30 are free of irregularities. As shown in FIG. 5, a resin sheet having a lot of foams 311 may be used for the surface layer sheets 31a and 31b.

The surface layer sheets 31a and 31b are preferably adhered to each other using a black adhesive (not shown). As described in connection with the first embodiment, this can prevent marks or letters on the front surface from being seen through the back surface.

According to the present embodiment, similarly to the manufacturing process described in connection with the first embodiment, a plurality of RFID tags 121 may be provided on the surface layer sheet 31a, the surface layer sheet 31b may be laminated thereon, and then playing cards 30 may be cut out by punching processing. In this way, the playing cards 30 can be produced efficiently. As described in connection with the first embodiment, printing is preferably carried out in advance to the surface layer sheets 31a and 31b.

Note that a printed sheet may be placed on the surface layer sheets 31a and 31b instead of directly carrying out printing to the surface layer sheets 31a and 31b.

Note that the RFID tag 121 may be produced by forming an IC chip and an antenna on a base material such as a resin sheet having a relatively small area, while, alternatively, if for example an RFID tag sheet having a plurality of RFID tags 121 formed on a single base material is commercially available from an RFID tag manufacturer or the like, the RFID tag sheet may be provided on the surface layer sheet 31b, the other surface layer sheet 31a may be laminated thereon, and then playing cards 30 may be cut out by punching processing.

Note that in the foregoing description, the surface layer sheets 31a and 31b both have plasticity, but only one of the surface layer sheets 31a and 31b may have plasticity, provided that the thickness of the RFID tag 121 can be absorbed.

As in the foregoing, in the playing card 30 according to the present embodiment, the RFID tag 121 is held between the surface layer sheets having plasticity. In this way, the RFID tag 121 can be incorporated without irregularities on the surface layers of the playing card 30.

In addition, in each of the embodiments described above, the playing card is shown as an example of the game card according to the invention, while the invention is applicable to various kinds of game cards other than the playing card.

### INDUSTRIAL APPLICABILITY

The invention has industrial applicability in the field of game cards.

1. A game card having an RFID tag held between at least two sheets, the RFID tag being held between the sheets as the RFID tag is incorporated in an intermediate layer having an approximately uniform thickness.

2. The game card according to claim 1, wherein the intermediate layer includes the RFID tag and at least two base films arranged to hold the RFID tag therebetween.

3. The game card according to claim 1, wherein the intermediate layer includes the RFID tag and a base film having the RFID tag embedded therein so that its surface does not protrude.

4. The game card according to claim 2, wherein the base film is colored black.

5. The game card according to claim 1, wherein the sheet and the intermediate layer are adhered to each other using a black adhesive.

6. The game card according to claim 2, wherein the at least two base films are adhered to each other using a black adhesive.

7. The game card according to claim 1, wherein the intermediate layer is an adhesive layer that adheres the at least two sheets.

8. The game card according to claim 7, wherein the adhesive layer is colored black.

9. A game card having an RFID tag held between at least two sheets, wherein at least one of the at least two sheets has a degree of plasticity that absorbs the thickness of the RFID tag.

10. The game card according to claim 9, wherein the sheet having plasticity contains foams.

11. The game card according to claim 9, wherein the sheet and the RFID tag are adhered to each other using a black adhesive.

12. A method of manufacturing a game card having an RFID tag-incorporated intermediate layer held between at least two sheets, the intermediate layer having an approximately uniform thickness, the method comprising the steps of:
having a plurality of RFID tags incorporated in the intermediate layer;
forming a layered body having the intermediate layer held between at least two sheets; and
cutting individual game cards out from the layered body.

13. A method of manufacturing a game card having an RFID tag held between at least two sheets including a sheet having a degree of plasticity that absorbs the thickness of the RFID tag, comprising the steps of:
providing a plurality of RFID tags on at least one of the two sheets;
forming a layered boy produced by providing at least one sheet on the sheet having the plurality of RFID tags provided thereon; and
cutting individual game cards out from the layered body.

14. The method of manufacturing a game card according to claim 12, comprising the step of printing a mark and/or a number on the surfaces of the sheets before the step of forming the layered body.

15. The method of manufacturing a game card according to claim 14, comprising the step of recording the plurality of RFID tags with pieces of information different from one another that correspond to the mark and/or the number printed on the sheets.
